(19) United States
(12) Patent Application Publication
(10) Pub. No.: US 2011/0140580 A1
(43) Pub. Date: Jun. 16, 2011

(54) METAL NONPARTICLE-POLYMER COMPOSITES, METHOD OF MANUFACTURING THE SAME, AND POLYMER ACTUATOR USING THE SAME

(75) Inventors: Kwang Suk YANG, Daejeon (KR); Nak Jin Choi, Daejeon (KR); Hyung Kun Lee, Daejeon (KR); Sun Kyung Jung, Daejeon (KR); Kang Ho Park, Daejeon (KR); Jong Dae Kim, Daejeon (KR)

(73) Assignee: Electronics and Telecommunications Research Institute, Daejeon (KR)

(21) Appl. No.: 12/908,285

(22) Filed: Oct. 20, 2010

(30) Foreign Application Priority Data
Dec. 14, 2009 (KR) 10-2009-0123748

(51) Int. Cl. H01L 41/193; H01B 1/22; B05D 5/12

(52) U.S. Cl. 310/363; 252/512; 427/123; 310/311; 977/777; 977/896; 977/948

(57) ABSTRACT

Metal nanoparticle-polymer composites, a method of manufacturing the same, and a polymer actuator using the same are provided. The method includes synthesizing an organometallic compound as a precursor of metal nanoparticles, preparing a solution mixture containing the organometallic compound and a polymer, and drying and annealing the solution mixture to generate the metal nanoparticle-polymer composite including metal nanoparticles. Thus, highly efficient metal nanoparticle-polymer composite materials may be manufactured with a uniform distribution without synthesizing nanoparticles.

### CROSS-REFERENCE TO RELATED APPLICATION

This application claims priority to and the benefit of Korean Patent Application No. 10-2009-0123748, filed Dec. 14, 2009, the disclosure of which is incorporated herein by reference in its entirety.

### BACKGROUND

1. Field of the Invention

The present invention relates to polymer composites, and more specifically, to metal nanoparticle-polymer composites.

2. Discussion of Related Art

Currently, with rapid developments in electrical, electronic, and energy technologies, highly efficient polymer nanoparticle composite materials have globally been required more and more in industries and fields that need excellent physical properties, and competition for research and patents on the polymer nanoparticle composite materials has accelerated. In particular, due to the increased demand for electrical applications of polymers having high chemical and optical properties, more attention is being paid to manufacture of conductive polymers and polymer composite films.

Meanwhile, a vast amount of research has been conducted on thin-film materials having high dielectric constants with rapid development of semiconductor technology. In particular, chemical vapor deposition (CVD) and sputtering techniques are mainly being adopted to form metal films, such as platinum (Pt) and palladium (Pd) films. Among these, Pt(acac)₂ (acac=acetylacetonate), Pt(CO)₂Cl₂, Pt(PF₃)₄, Pt(CH₃)₂[(CH₃)NC], (COD)Pt(CH₃)₂, (COD)Pt(CH₃)(η1—C₅H₅), (COD)Pt(CH₃)Cl, (C₅H₅)Pt(CH₃)(CO), (C₅H₅)Pt(allyl), (acac)Pt(CH₃)₃, (C₅H₅)Pt(CH₃)₃, (CH₃C₅H₄)Pt(CH₃)₃, and Pt(hfacac)₂ have been used as Pt film deposition materials, and [Pd(η3-allyl)₂], [Pd(η3—CH₂CHM₂)₂], [Pd(η5-C₅H₅)(η3-allyl)], [cis-[PdMe₂L₂](L=PMe₃ or PEt₃), [Pd{OC(R)CHC(R)O}₂](R=Me, CF₃), and [Pd(η3—CH₂CHCHCH₂)(fod)] have been used as Pd film deposition materials.

Afterwards, four kinds of organometallic compounds newly synthesized using coatable colloidal solutions or by synthesis of new Pt and Pd organic compounds and methods of forming solution films using the organometallic compounds have been reported.

However, since the above-described conventional techniques of manufacturing nanoparticle-polymer composites mainly employ previously synthesized nanoparticles, an additional process of preparing nanoparticles may be required, and aggregation and precipitation may occur during a mixture of the nanoparticle-polymer composite with a polymer liquid.

### SUMMARY OF THE INVENTION

The present invention is directed to metal nanoparticle-polymer composites having a uniform distribution, which may reduce organometallic compounds to metal nanoparticles in a polymer liquid mixed with the organometallic compounds using the principle that metal ions are reduced to metal nanoparticles due to thermal stimuli, and a method of manufacturing the same.

The present invention is also directed to an ionic polymer metal composite (IPMC) actuator using the metal nanoparticle-polymer composites and a method of manufacturing the same.

One aspect of the present invention is to provide a method of manufacturing a metal nanoparticle-polymer composite. The method includes: synthesizing an organometallic compound as a precursor of metal nanoparticles; preparing a solution mixture containing the organometallic compound and a polymer; and drying and annealing the solution mixture to generate the metal nanoparticle-polymer composite including metal nanoparticles.

The preparation of the solution mixture may include: dissolving the organometallic compound and the polymer in solvents to prepare an organometallic compound solution and a polymer solution; and mixing the organometallic compound solution with the polymer solution to prepare the solution mixture.

The preparation of the solution mixture may include: dissolving the polymer in a solvent to prepare a polymer solution; and mixing the polymer solution with the organometallic compound to prepare the solution mixture.

The preparation of the solution mixture may include: applying heat, or heat and pressure to the polymer to prepare a polymer melt solution and dissolving the organometallic compound in a solvent to prepare an organometallic compound solution; and mixing the polymer melt solution with the organometallic compound solution to prepare the solution mixture.

The organometallic compound may be one selected from the group consisting of platinum (Pt), palladium (Pd), gold (Au), silver (Ag), copper (Cu), cobalt (Co), ruthenium (Ru), rhodium (Rh), iridium (Ir), tantalum (Ta), titanium (Ti), tungsten (W), and a mixture thereof.

The polymer may be any polymer capable of being prepared in or changed into a liquid phase.

A ratio of the organometallic compound used as a precursor and the polymer may be controlled to control the concentration of metal nanoparticles in the generated metal nanoparticle-polymer composite.

The solution mixture may be dried at a temperature of about 50 to 200° C.

The solvent of the organometallic compound solution or the solvent of the polymer solution may be one selected from the group consisting of water, ethanol, methanol, isopropanol, 1,2-dichlorobenzene, chloroform, dimethylformamide (DMF), acetone, N-methylpyrrolidone (NMP) and a mixture thereof.

The drying of the solution mixture may include injecting the solution mixture into a mold and drying the solution mixture to control the shape and size of the metal nanoparticle-polymer composite.

The drying of the solution mixture may be performed using one selected from the group consisting of a doctor blade coating process, a spin coating process, a spin casting process, a roll coating process, and a deep coating process.

The properties of the metal nanoparticle-polymer composite may be controlled by at least one selected from the group consisting of a chemical structure, concentration, annealing temperature, and annealing time of a metal precursor and viscosity and content of the polymer.

The drying of the solution mixture may include aligning a heat source to one side of the metal nanoparticle-particle composite to manufacture the metal nanoparticle-polymer composite having both sides with different electrical properties.

The electrical properties of the metal nanoparticle-polymer composite may depend on at least one condition selected from the group consisting of the number, arrangement, shape, size, and temperature gradient of heat sources.

Another aspect of the present invention is to provide a metal nanoparticle-polymer composite manufactured according to a method of manufacturing a metal nanoparticle-polymer composite according to an exemplary embodiment of the present invention.

Still another aspect of the present invention is to provide a polymer actuator manufactured by processing the metal nanoparticle-polymer composite using plasma, cleaning the metal nanoparticle-polymer composite using a solution, forming electrodes, and substituting the metal nanoparticle-polymer composite for a lithium electrolyte.

The electrode may be a Pt electrode.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 is a flowchart illustrating a method of manufacturing metal nanoparticle-metal composites and a method of manufacturing a polymer actuator using the metal nanoparticle-polymer composites using the method according to an exemplary embodiment of the present invention;

FIG. 2 is a graph showing thermo gravimetric analysis (TGA) results of platinum (Pt) compounds synthesized as precursors of metal nanoparticles;

FIG. 3 is a diagram of a drying apparatus configured to dry a solution mixture containing organometallic compounds (or metal complexes) and temperatures at which the solution mixture is dried, according to an exemplary embodiment of the present invention;

FIG. 4 is a schematic diagram showing an annealing process using a hydraulic press of a thermal plate of a polymer film containing organometallic compounds (or metal complexes) according to an exemplary embodiment of the present invention;

FIG. 5 is a schematic diagram showing comparison between a polymer film containing molecular organic metal complexes and a polymer composite containing metal nanoparticles according to an exemplary embodiment of the present invention;

FIG. 6A is a diagram of a polymer film containing metal nanoparticles manufactured using a method of manufacturing metal nanoparticle-polymer composites according to an exemplary embodiment of the present invention;

FIG. 6B is a scanning electronic microscope (SEM) photograph showing the section of a polymer film containing the metal nanoparticles of FIG. 6A;

FIG. 7A is a schematic diagram of a polymer actuator containing Pt and palladium (Pd) nanoparticles according to an exemplary embodiment of the present invention;

FIG. 7B is a graph showing a comparison between polymer actuators of FIG. 7A containing Pt and Pd nanoparticles, and conventional polymer actuators in displacements and driving force; and

FIG. 7C is a graph showing estimation results of the displacements and driving force of polymer actuators including Pt and Pd nanoparticles of FIG. 7B.

### DETAILED DESCRIPTION OF EXEMPLARY EMBODIMENTS

The present invention will now be described more fully hereinafter with reference to the accompanying drawings, in which exemplary embodiments of the invention are shown. This invention may, however, be embodied in different forms and should not be construed as limited to the embodiments set forth herein. Rather, these embodiments are provided so that this disclosure is thorough and complete and fully conveys the scope of the invention to those skilled in the art. For brevity, components irrelevant to the description of the embodiments may be omitted in the drawings, and like numbers refer to like elements throughout.

It will be understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof unless the context clearly indicated otherwise.

Hereinafter, a process of preparing a metal nanoparticle-precursor solution, a process of mixing the metal nanoparticle-precursor solution with a polymer melt solution, and a process of forming a forming layer will be described in further detail to manufacture a metal nanoparticle-polymer composite layer.

In order to prepare a Pt, Au, or Pd nanoparticle solution that does not form colloids or aggregates, and uniformly dissolve the nanoparticle solution on a polymer melt solution to form a desired shape or film, a large number of complicated process operations may be required. In particular, distribution uniformity may significantly affect fundamental performance in electrical and electronic fields.

To control the concentration of metal nanoparticles in a polymer liquid, a process of manufacturing a metal nanoparticle-polymer composite film should be performed under the following conditions in consideration of time and cost.

First, the metal nanoparticle-polymer composite film should be easily handled using various processes irrespective of the kind and physical properties of a polymer. The metal nanoparticle-polymer composite film may be easily mixed with a polymer having various properties, such as a liquid or block copolymer or a conductive polymer, and the concentration of the metal nanoparticle-polymer composite film should be easily controlled.

Second, the metal nanoparticle-polymer composite film should be easily obtained by applying various concentrations of nanoparticles and various thicknesses of polymer layers. Since the metal nanoparticle-polymer composite film should be generally used to manufacture composite layers for various purposes, a process of aligning carbon nanoparticles should be constantly reacted with external stimuli.

Third, the metal nanoparticle-polymer composite film should be flexibly applied also in conditions under which other additional materials, such as carbon nanotubes, graphene, or metal oxide particles, are adopted. Since polymer materials used in practical industries are in environments where various fillings for making up for poor mechanical properties of the polymer materials may be employed, the polymer materials should be neither physically nor chemically adsorbed on the fillings nor should they react with the fillings.

To satisfy the three above-described conditions, a precursor of metal nanoparticles may be synthesized or a commercial material may be purchased without previously synthesizing metal nanoparticles before preparing composites, and the metal nanoparticles may be delocalized in a polymer liquid state to form uniform composite layers. The properties of the composite layers may be mainly controlled by the chemical structure and concentration of the metal precursor, annealing temperature and time, and the viscosity and content of a polymer and experimentally optimized.

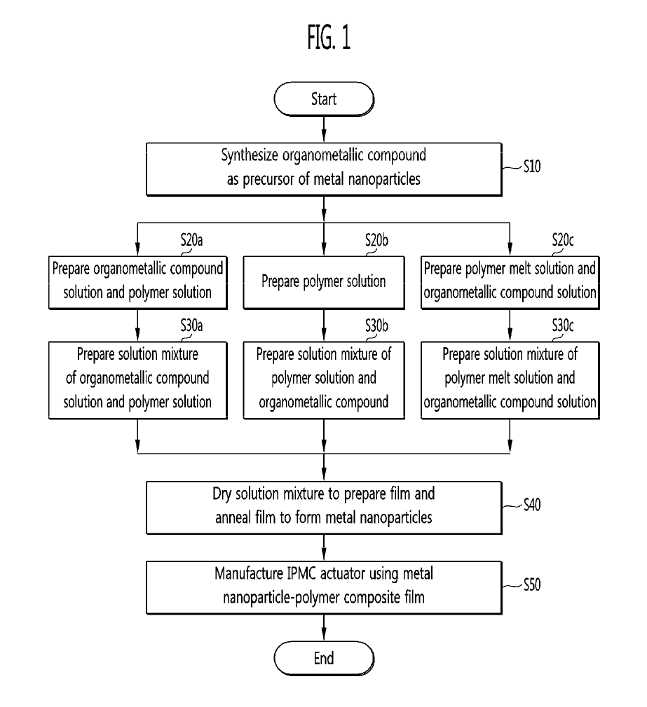

FIG. 1 is a flowchart illustrating a method of manufacturing metal nanoparticle-metal composites and a method of manufacturing a polymer actuator using the metal nanoparticle-polymer composites using the method according to an exemplary embodiment of the present invention.

Hereinafter, a method of manufacturing metal nanoparticle-metal composite films according to an exemplary embodiment of the present invention will be described. Although the metal nanoparticle-metal composite films are described, metal nanoparticle-polymer composites are not limited to films.

To begin with, an organometallic compound may be synthesized (operation S10) as a precursor of metal nanoparticles.

A thermal decomposition temperature may be controlled to a temperature of about 50 to 200° C. using thermo gravimetric analysis (TGA) of an organometallic compound according to the present invention.

### Embodiment

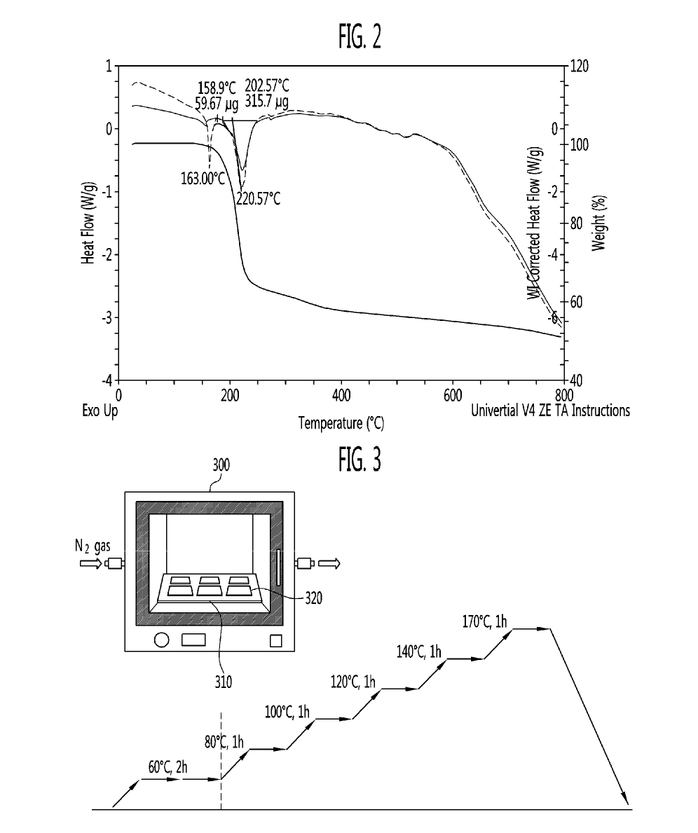

FIG. 2 is a graph showing TGA results of platinum (Pt) compounds synthesized as precursors of metal nanoparticles.

Trans-Pt(DMS0)(NH₂CH₂CH₂OH)Cl₂(or trans-Pd(DMSO)(NH₂CH₂CH₂OH)Cl₂) was synthesized as a precursor of Pt (or Pd) nanoparticles using inorganic synthesis.

Hereinafter, processes of synthesizing trans-Pt(DMSO)(NH₂CH₂CH₂OH)Cl₂ and trans-Pd(DMSO)(NH₂CH₂CH₂OH)Cl₂) will be described.

Synthesis of trans-Pt(DMSO)(NH₂CH₂CH₂OH)Cl₂

Potassium tetrachloro platinate (II) (0.5 g, 1.2 mmol) was added and completely dissolved in 7 ml distilled water, and dimethyl sulfoxide (DMSO) (0.255 ml, 3.6 mmol) was added and stirred for 5 hours at room temperature, thereby obtaining cis-Pt(DMSO)₂Cl₂ as a pale yellow solid. After filtering cis-Pt(DMSO)₂Cl₂, cis-Pt(DMSO)₂Cl₂ was cleaned using H₂O, ether, and alcohol and dried using a vacuum oven.

After cis-Pt(DMSO)₂Cl₂ (0.5 g, 1.18 mmol) was completely dissolved in 100 ml CH₂Cl₂, ethanol amine (0.0715 ml, 1.18 mmol) was added to the solution, stirred for 5 minutes and let to sit for 3 hours. After a white powdered precipitate was formed, yellow crystals started to be generated within 10 hours, and the white powdered precipitate was removed by filtering. The remaining filtrate was condensed into a 5 ml solution using vacuum distillation and recrystallized into n-hexane, thereby obtaining a yellow solid.

Synthesis of trans-Pd(DMSO)(NH₂CH₂CH₂OH)Cl₂

Palladium chloride (0.25 g, 1.4 mmol) was added to DMSO (5 ml, 0.07 mmol) and stirred for 1 hour at a temperature of about 50° C., and ethyl ether was added to the solution, thereby obtaining trans-Pd(DMSO)₂Cl₂ as saffron yellow. After filtering trans-Pd(DMSO)₂Cl₂, the trans-Pd(DMSO)₂Cl₂ was cleaned using ether and dried using a vacuum oven.

After trans-Pd(DMSO)₂Cl₂ (0.1 g, 0.3 mmol) was completely dissolved in 100 ml CH₂Cl₂, ethanol amine (0.0181 ml, 0.3 mmol) was added, stirred for 5 minutes, and let to sit. The solution was condensed into a 5 ml solution using vacuum distillation and recrystallized into n-hexane, thereby obtaining pale yellow powder.

On analysis of the TGA results of trans-Pt(DMSO)(NH₂CH₂CH₂OH)Cl₂ synthesized with reference to FIG. 2, relatively high values of 59.67 J/g and 315.7 J/g were obtained at temperatures of about 158.92° C. and about 202.57° C. than at other temperatures. Thus, it can be seen that the masses of precursors synthesized at the temperatures of about 158.92° C. and about 202.57° C. were largely varied.

A precursor according to an exemplary embodiment will now be described. A metal element of the precursor may not be specially limited to Pt and Pd, which are described in the present embodiment, and one skilled in the art may select and apply the kind and molecular structure of the precursor without departing from the spirit of the present invention. For example, gold (Au), copper (Cu), ruthenium (Ru), rhodium (Rh), iridium (Ir), tantalum (Ta), titanium (Ti), or tungsten (W) may be used instead of Pt or Pd.

Next, an organometallic compound solution and a polymer solution may be prepared (operation S20a).

According to another embodiment, only a polymer solution may be prepared (operation S20b).

According to yet another embodiment, a polymer melt solution and an organometallic compound solution may be prepared (operation S20c).

Here, the polymer melt solution may refer to a liquid solution prepared by applying heat, or heat and pressure irrespective of use or disuse of a solvent.

Any solvent capable of dissolving an organometallic compound, a polymer, or a monomer may be used as a solvent of an organometallic compound or a solvent of a polymer solution. Also, the solvent of the organometallic compound or the solvent of the polymer solution should be mixed with an intended solution.

The solvent may be water, an organic solvent, or a mixture thereof The organic solvent may be ethanol, methanol, isopropanol, 1,2-dichlorobenzene, chloroform, DMF, or acetone. The polymer melt solution may contain 5 to 10,000 parts by weight solvent, based on 1 part by weight total solids, and contain 0.0001 to 10 parts by weight organometallic compound, based on 100 parts by total weight polymer melt solution.

### Embodiment

A Pt or Pd complex (trans-Pt(DMSO)(NH₂CH₂CH₂OH)Cl₂ or trans-Pd(DMSO)(NH₂CH₂CH₂OH)Cl₂)) was dissolved in dimethylformamide (DMF) as a solvent, thereby preparing a 50 mg/mL organometallic compound solution. Also, a 20 wt % Nafion solution as a polymer matrix was mixed with DMF in a mixture ratio of 5:1 and prepared.

Thereafter, a solution mixture of the organometallic compound solution and the polymer solution may be prepared (operation S30a). [{(polymer+solvent)+(organometallic compound+solvent)}=solution mixture]

According to another embodiment, the polymer solution may be mixed with the organometallic compound, thereby preparing a solution mixture (operation S30b). [{(polymer+solvent)+organometallic compound}=solution mixture]

According to yet another embodiment, a polymer melt solution may be mixed with an organometallic compound solution, thereby preparing a solution mixture (operation S30c). [{polymer melt solution+(organometallic compound+solvent)}=solution mixture]

Therefore, a method of preparing the solution mixture in the method of manufacturing the metal nanoparticle-polymer composite according to the exemplary embodiment of the present invention may include ‘\hat{1}{(polymer+solvent)+(organometallic compound+solvent)}=solution mixture’, ‘\textcircled{2}{(polymer+solvent)+organometallic compound}=solution mixture’, or ‘\textcircled{3}{polymer melt solution+(organometallic compound+solvent)}=solution mixture’.

The solution mixture may contain 0.001 to 10 parts by weight based on 100 parts by weight total solids of the solution mixture. When the solution mixture contains less than 0.001 parts by weight organometallic compound as a precursor of metal nanoparticles, the efficiency of formation of the metal nanoparticles may be reduced. When the solution mixture contains more than 10 parts by weight organometallic compound, it may be difficult to form nanoparticles to a uniform size with a uniform distribution, and part of the organometallic compound may leak during a thermal reduction process to form a metal film. As a result, the electrical properties of the surface of the final metal nanoparticle-polymer film may become non-uniform.

Meanwhile, when formation of a metal film is artificially induced by partially leaking the organometallic compound, the organometallic compound contained in the solution mixture may be increased to 10 to 30 parts by weight so that a metal nanoparticle-polymer composite on which a metal film is coated can be manufactured in situ. This method may be performed in consideration of a drying method and time.

In the manufacture of metal nanoparticle-particle layers according to the present invention, a ratio of an organometallic compound used as a precursor and a polymer in a solution mixture may be controlled to obtain a highly conductive composite. It is well known that chemical stabilization required to manufacture a highly uniform metal nanoparticle-polymer solution mixture and preserve the solution mixture for a long period is an inhibitor to manufacture of electrodes. Although a low-resistant polymer flexible electrode may be manufactured by applying a magnetic field to a metal nanoparticle solution with a high concentration, it does not mean that the low-resistant polymer flexible electrode may replace conventional carbon nanotubes, graphene, or metal oxide electrodes.

### Embodiment

A Pt compound may be controlled to contents of 3 mg and 6 mg for each 1 cm²×0.25 mm (thickness) final film, thereby manufacturing a Pt complex-Nafion solution mixture.

Thereafter, the solution mixture may be dried to prepare a film (or thin film), and the film may be annealed to form metal nanoparticles (operation S40).

Before preparing the film by drying the solution mixture, the solution mixture may be injected into a mold to dry the solution mixture.

The film according to an exemplary embodiment of the present invention may be manufactured to various shapes and sizes according to the shape of the mold. If the kinds and materials of the film may not chemically affect a final film and capable of being easily detached, any film may be used.

In addition to the mold process, the film may be prepared using various methods, for example, a doctor blade coating process, a spin coating process, a spin casting process, a roll coating process, or a deep coating process in consideration of the physical properties of the solution mixture.

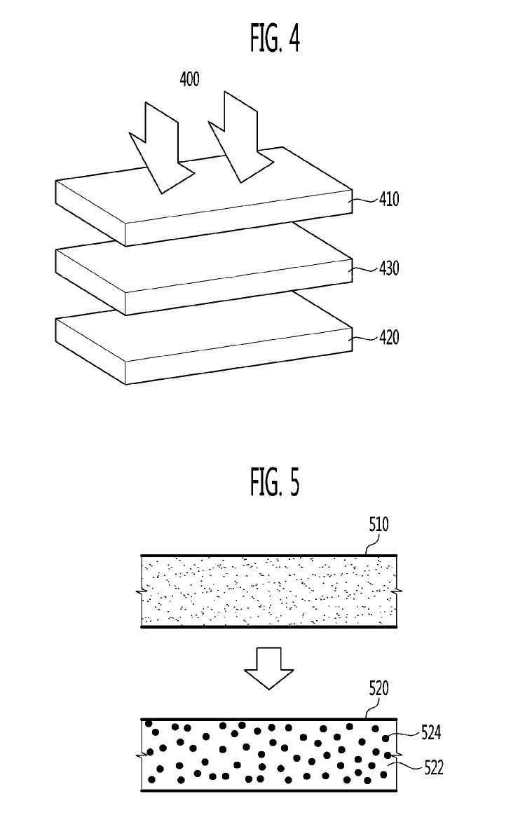

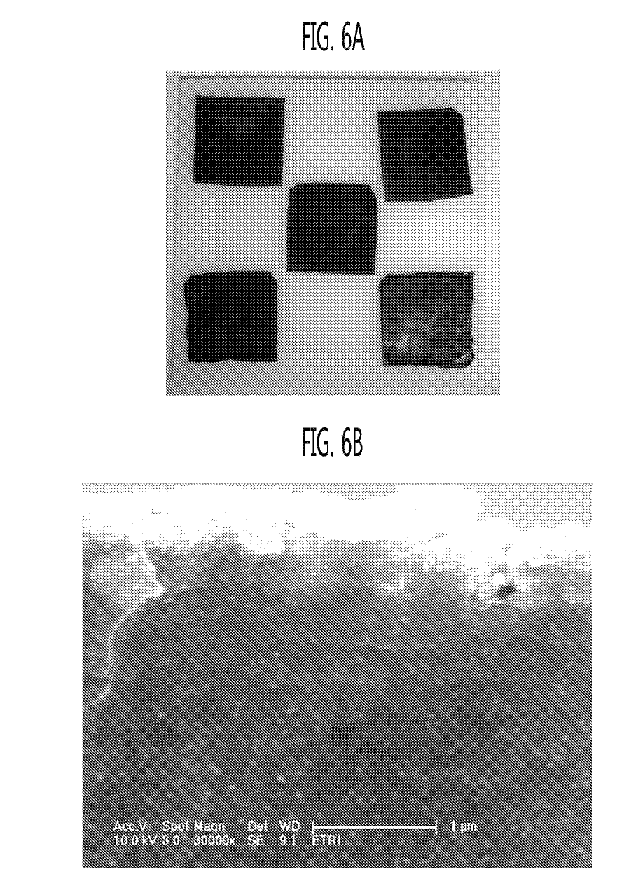

FIG. 3 is a diagram of a drying apparatus configured to dry a solution mixture containing organometallic compounds (or metal complexes) and temperatures at which the solution mixture is dried, according to an exemplary embodiment of the present invention, and FIG. 4 is a schematic diagram showing an annealing process using a hydraulic press of a thermal plate of a polymer film containing organometallic compounds (or metal complexes) according to an exemplary embodiment of the present invention.

The drying method may include at least two temperature setting periods. However, a large amount of solvent may be previously removed or vacuum or pressure may be applied during a drying process according to states (e.g., viscosity and physical and chemical properties of the solvent) and the area and thickness of a desired final film.

Referring to FIG. 3, a drying apparatus 300 configured to dry a solution mixture containing an organometallic compound (or metal complex) may be a vacuum oven, and nitrogen (N₂) gas may be injected to vacuumize the drying apparatus 300. A glass plate 310 may be loaded in the drying apparatus 300, and a silicon-elastomer well 320 may be mounted on the glass plate 310. The solution mixture may be dried for 2 hours at a temperature of about 60° C. Thereafter, the solution mixture may be interposed between silicon pads and dried on a hot plate for 1 hour at a temperature of about 80° C. Thereafter, the solution mixture may be annealed for 1 hour at a temperature of about 100° C., annealed for 1 hour at a temperature of about 120° C. annealed for 1 hour at a temperature of about 140° C., annealed for 1 hour at a temperature of about 170° C., and naturally cooled.

To obtain the drying temperature, a temperature at which a mixed organometallic compound is reduced may be experimentally obtained using a thermal analysis apparatus, such as a TGA apparatus or a DSC apparatus, the mixed organometallic compound may be dried for five minutes to 24 hours at a temperature of about 30 to 200° C. The TGA apparatus may vary the temperature of a sample and measure a variation in the mass of the sample as a temperature function. The DSC apparatus may vary the temperatures of a sample and a reference and measure a difference in energy input between the sample and the reference as a temperature function. The solution mixture may be solidified using a drying process or polymerization process, thereby manufacturing an ‘in situ metal nanoparticle-polymer composite film’.

Referring to FIG. 4, after the polymer film containing the organometallic compound (or metal complex) is manufactured using a drying process, a thermal process using a thermal-plate hydraulic press may be performed to form metal nanoparticles.

Specifically, when a polymer film (e.g., Nafion film) 430 containing the prepared organometallic compound (or metal complex) is inserted into the thermal-plate hydraulic press 400, the polymer film 430 containing the organometallic compound may be interposed between a hydraulic-press upper plate 410 and a hydraulic-press lower plate 420, and the hydraulic-press upper and lower plates 410 and 420 may be annealed using a thermal compression process so that metal nanoparticles can be formed in the polymer film.

In the method according to the embodiment of the present invention, a composite layer may be formed to a constant size with a uniform distribution. When a thermal source for a reduction reaction is aligned on one side of the composite layer, a concentration gradient of particles may be formed or particles with different sizes may be induced on both sides of the composite layer, so that the both sides of the composite layer can have different electrical properties. The composite layer may be modified and applied under various external conditions, such as the number, arrangement, shape, size, and temperature gradients of thermal sources.

To obtain desired physical and chemical properties, shape, and thickness of the composite layer and to allow efficient evaporation of the used solvent, a temperature, a degree of vacuum, and the increasing or decreasing rates and gradients of temperature and vacuum should be controlled according to the content of the final metal nanoparticles. It should be appreciated to those skilled in the art that a variety of modifications and changes can be made without departing from the spirit and scope of the present invention.

### Embodiment

A solvent of a solution mixture was dried using a glass mold for 12 hours at room temperature at a humidity of about 20±3%.

Thereafter, the solution mixture was dried in an oven for 12 hours by gradually increasing an atmospheric room-temperature to a temperature of about 140° C., thereby preparing a Nafion composite layer containing Pt (or Pd) nanoparticles.

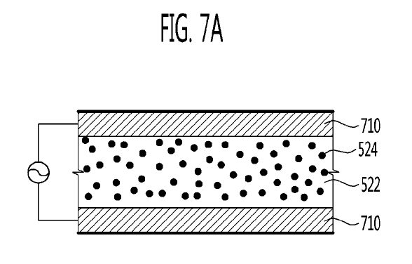

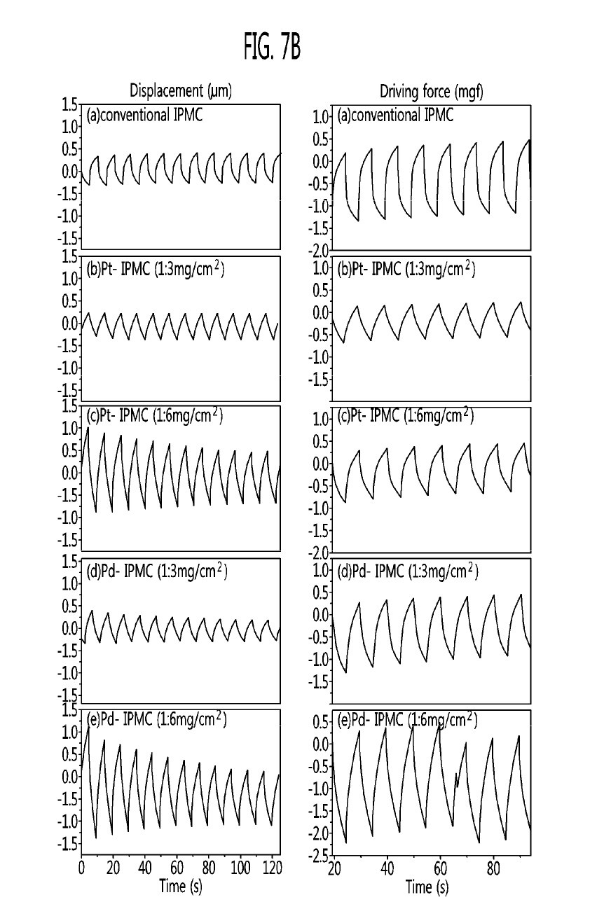

FIG. 5 is a schematic diagram showing comparison between a polymer film containing molecular organic metal complexes and a polymer composite containing metal nanoparticles according to an exemplary embodiment of the present invention, FIG. 6A is a diagram of a polymer film containing metal nanoparticles manufactured using a method of manufacturing metal nanoparticle-polymer composites according to an exemplary embodiment of the present invention, and FIG. 6B is a scanning electronic microscope (SEM) photograph showing the section of a polymer film containing the metal nanoparticles of FIG. 6A.

Referring to FIGS. 5, 6A, and 6B, in an unannealed organometallic compound-polymer mixture 510, an organometallic compound may be contained in a molecular state in a polymer mixture. Afterwards, as described above with reference to FIG. 4, the organometallic compound-polymer mixture 510 may be annealed using a thermal-plate hydraulic press. As a result, a metal nanoparticle-polymer composite 520 may contain a polymer 522 and metal nanoparticles 524.

Finally, an ionic polymer-metal composite (IPMC) actuator may be manufactured using the metal nanoparticle-Nafion composite film (i.e., metal nanoparticle-polymer film) obtained through operations S10 to S40 (operation S50).

The manufacture of the IPMC actuator may involve processing the metal nanoparticle-polymer composite film using pre-cleaning and oxygen plasma treatment, forming electrodes by electroless or electro-plating, and substituting the internal solvent molecules of metal nanoparticle-polymer composite film for a lithium electrolyte.

### Embodiment

A Pt electrode was used as an electrode required for manufacture of an IPMC actuator, and a complex for forming the Pt electrode was selected out of [Pt(NH₃)₄]Cl₂ and [Pt(NH₃)₆]Cl₄.

A process of reducing a Pt complex for forming the Pt electrode may include a primary reduction process and a secondary reduction process. The primary reduction process was performed using NaBH₄, and the secondary reduction process was performed using NH₂NH₂-1˜1.5 H₂O (hydrazine hydrate) or NH₂OH—HCl.

Hereinafter, a Pt plating process for forming a Pt electrode required for manufacture of an IPMC actuator will be described.

The concentration of a Pt solution was 2 mg Pt/ml, and the amount of Pt per area of a Nafion film was maintained at a value of 3 mg/cm² or more. A 30 cm² Nafion film was dipped in a 45 ml Pt solution for 4 hours or more to sufficiently adsorb a Pt complex, and dipped in a 5% ammonia solution (1 ml) and neutralized at room temperature for 3 hours or more.

A 5 wt % NaBH₄ solution and the 30 cm² Nafion film, which was properly cleaned using deionized water, were prepared. The 30 cm² Nafion film was put in a water tank containing deionized water (40° C., 180 ml), the 5 wt % NaBH₄ solution (2 ml) was dividedly added to the water tank seven times at time intervals of 30 minutes, and the water tank was gradually heated to a temperature of about 60° C.

Afterwards, a 5 wt % NaBH₄ solution (20 ml) was additionally injected at a temperature of about 60° C. and the water tank was stirred for 1.5 hours. After a reaction ended, the 30 cm² Nafion film was cleaned using deionized water and dipped in a 0.1 N hydrochloric solution for 1 hour.

Due to the above-described primary reduction process, the Nafion film was plated with a 0.9 mg/cm² Pt layer. To additionally plate the Nafion film with a 2 mg/cm² Pt layer per unit area, a 240 ml solution containing a 120 mg Pt compound was required, and a 5% ammonia water (5 ml) was added to prepare a plating solution. The Nafion film was dipped in a 40° C. Pt solution and stirred for 30 minutes. After that, a 20% NH₂OH—HCl (6 ml) was put in the water tank, and a 20% hydrazine solution (3 ml) was injected at time intervals of about 30 minutes.

Subsequently, the temperature of the solution was gradually raised to a temperature of about 60° C. over 4 hours, thereby preparing a film with a gray surface.

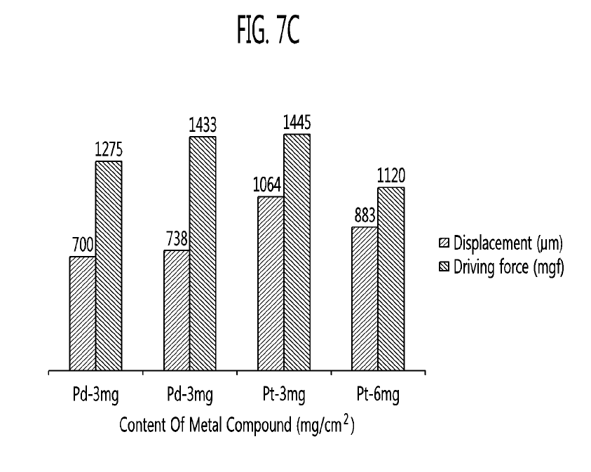

FIG. 7A is a schematic diagram of a polymer actuator containing Pt and Pd nanoparticles according to an exemplary embodiment of the present invention, FIG. 7B is a graph showing a comparison between polymer actuators of FIG. 7A containing Pt and Pd nanoparticles, and conventional polymer actuators in displacements and driving force, and FIG. 7C is a graph showing estimation results of the displacements and driving force of polymer actuators including Pt and Pd nanoparticles of FIG. 7B.

Referring to FIG. 7A, polymer actuators including Pt and Pd nanoparticles according to exemplary embodiments of the present invention may include electrodes 710 formed on and under a metal nanoparticle-polymer film including a polymer 522 and metal nanoparticles 524. For example, the polymer may be Nafion. As described above, Pt electrodes may be used as the electrodes 710.

### EXPERIMENTAL EXAMPLE

### Measurement of Displacement and Driving Force

The displacements of 3×8 mm² strip-type polymer actuators were measured by applying a voltage of about 3 V (0.1 Hz) using a frequency generator.

Referring to FIG. 7B, the polymer actuators including the Pt and Pd nanoparticles according to the exemplary embodiment of the present invention exhibited much better performances than conventional polymer actuators. Both the polymer actuators including the Pt and Pd nanoparticles had higher displacements than the conventional polymer actuators, and similar or better driving force than the conventional polymer actuators.

Referring to FIG. 7C, it can be seen that when the content of a Pd metal compound was increased from 3 mg to 6 mg, the displacement of the metal compound was increased from 700 μm to 738 μm, and the driving force of the metal compound was increased from 1275 mgf to 1433 mgf. Conversely, it can be seen that when the content of a Pt compound was increased from 3 mg to 6 mg, the displacement of the Pt compound was reduced from 1064 μm to 883 μm, and the driving force of the Pt compound was reduced from 1445 mgf to 1120 mgf. However, it can be observed that both the Pd and Pt compounds had high displacements and driving force even at a low driving voltage of about 3 V.

Accordingly, when a polymer actuator is manufactured using a metal nanoparticle-polymer composite manufactured using the method according to the exemplary embodiment of the present invention, the polymer actuator may have good performance.

According to the method of manufacturing the polymer composite film including metal nanoparticles according to the present invention, the metal nanoparticles may have a high particle uniformity and a wide concentration range so that various metal nanoparticle composite materials may be easily manufactured at low cost using various polymer composite material manufacturing processes without adding unnecessary reducing agents. In particular, high-quality metal nanoparticle composite materials may be applied to a wide range of advanced industrial fields, such as flexible conducting film, chemical & physical sensors, fuel cell layers, flexible solar cells, polymer-based piezoelectricity, optoelectronic coating, catalysis, detection and decomposition of environmental pollutants, health & medical application, and clothings, and so on.

According to the exemplary embodiments of the present invention as described above, an organometallic compound may be dissolved as a raw metal material in a molecular state in a polymer melt solution without additionally preparing metal nanoparticles, and reduced to metal nanoparticles in a polymer liquid state in situ so that highly uniform metal nanoparticle-polymer composites can be manufactured in uniform distribution with high efficiency using an inexpensive process. Accordingly, the metal nanoparticle-polymer composites and methods of manufacturing the same may be applied to manufacture not only transparent, flexible conductive polymer composite materials (e.g., materials of electrical, electronic, and optical components) but also various highly efficient polymer composite materials and environmental catalysts, for example, electroactive polymers such as IMPCs, environmentally friendly energy materials such as various fuel cells and dye-sensitized solar cells, and haptic-related information technology (IT) materials.

Although exemplary embodiments of the present invention have been described with reference to the attached drawings, the present invention is not limited to these embodiments, and it should be appreciated to those skilled in the art that a variety of modifications and changes can be made without departing from the spirit and scope of the present invention.

What is claimed is:

1. A method of manufacturing a metal nanoparticle-polymer composite, the method comprising:
synthesizing an organometallic compound as a precursor of metal nanoparticles;
preparing a solution mixture containing the organometallic compound and a polymer; and
drying and annealing the solution mixture to generate the metal nanoparticle-polymer composite including metal nanoparticles.

2. The method of claim 1, wherein preparing the solution mixture comprises:
dissolving the organometallic compound and the polymer in solvents to prepare an organometallic compound solution and a polymer solution; and
mixing the organometallic compound solution with the polymer solution to prepare the solution mixture.

3. The method of claim 1, wherein preparing the solution mixture comprises:
dissolving the polymer in a solvent to prepare a polymer solution; and
mixing the polymer solution with the organometallic compound to prepare the solution mixture.

4. The method of claim 1, wherein preparing the solution mixture comprises:
applying heat, or heat and pressure to the polymer to prepare a polymer melt solution and dissolving the organometallic compound in a solvent to prepare an organometallic compound solution; and
mixing the polymer melt solution with the organometallic compound solution to prepare the solution mixture.

5. The method of claim 1, wherein the organometallic compound is one selected from the group consisting of platinum (Pt), palladium (Pd), gold (Au), silver (Ag), copper (Cu), cobalt (Co), ruthenium (Ru), rhodium (Rh), iridium (Ir), tantalum (Ta), titanium (Ti), tungsten (W), and a mixture thereof.

6. The method of claim 1, wherein the polymer is any polymer capable of being prepared in or changed into a liquid phase.

7. The method of claim 1, wherein a ratio of the organometallic compound used as a precursor and the polymer is controlled to control the concentration of metal nanoparticles in the generated metal nanoparticle-polymer composite.

8. The method of claim 1, wherein the solution mixture is dried at a temperature of about 50 to 200° C.

9. The method of claim 2, wherein the solvent of the organometallic compound solution or the solvent of the polymer solution is one selected from the group consisting of water, ethanol, methanol, isopropanol, 1,2-dichlorobenzene, chloroform, dimethylformamide (DMF), acetone, N-methylpyrrolidone (NMP) and a mixture thereof.

10. The method of claim 1, wherein drying the solution mixture comprises injecting the solution mixture into a mold and drying the solution mixture to control the shape and size of the metal nanoparticle-polymer composite.

11. The method of claim 1, wherein drying the solution mixture is performed using one selected from the group consisting of a doctor blade coating process, a spin coating process, a spin casting process, a roll coating process, and a deep coating process.

12. The method of claim 1, wherein the properties of the metal nanoparticle-polymer composite are controlled by at least one selected from the group consisting of a chemical structure, concentration, annealing temperature, and annealing time of a metal precursor and viscosity and content of the polymer.

13. The method of claim 1, wherein drying the solution mixture comprises aligning a heat source to one side of the metal nanoparticle-particle composite to manufacture the metal nanoparticle-polymer composite having both sides with different electrical properties.

14. The method of claim 13, wherein the electrical properties of the metal nanoparticle-polymer composite depend on at least one condition selected from the group consisting of the number, arrangement, shape, size, and temperature gradient of heat sources.

15. A metal nanoparticle-polymer composite manufactured by a method, the method comprising:
synthesizing an organometallic compound as a precursor of metal nanoparticles;
preparing a solution mixture containing the organometallic compound and a polymer; and
drying and annealing the solution mixture to generate the metal nanoparticle-polymer composite including metal nanoparticles.

16. A polymer actuator manufactured by processing the metal nanoparticle-polymer composite of claim 15 using pre-cleaning and oxygen plasma treatment, forming electrodes by electroless or electro-plating, and substituting the internal solvent molecules of the metal nanoparticle-polymer composite for a lithium electrolyte.

17. The polymer actuator of claim 16, wherein the electrode is a platinum (Pt) electrode.
